(19) United States
(12) Patent Application Publication
(10) Pub. No.: US 2014/0091209 A1
(43) Pub. Date: Apr. 3, 2014

(54) RADIATION DETECTING APPARATUS AND RADIATION DETECTING SYSTEM

(71) Applicant: CANON KABUSHIKI KAISHA, Tokyo (TW)

(72) Inventors: Taiki Takei, Okegawa-shi (JP); Masato Inoue, Kumagaya-shi (JP); Shinichi Takeda, Honjo-shi (JP); Satoru Sawada, Fujioka-shi (JP); Takamasa Ishii, Honjo-shi (JP); Kota Nishibe, Honjo-shi (JP)

(21) Appl. No.: 14/040,325

(22) Filed: Sep. 27, 2013

(30) Foreign Application Priority Data
Oct. 1, 2012 (JP) 2012-219633

(51) Int. Cl. H01L 27/144

(52) U.S. Cl. CPC H01L 27/144
USPC 250/216

(57) ABSTRACT

A radiation detecting apparatus includes a sensor panel that has photoelectric conversion elements; a light source unit that has a light guide plate, a light-emitting source disposed at a side surface of the light guide plate, a diffusing plate disposed at one surface of the light guide plate, and a reflective plate disposed at an opposite surface of the light guide plate; and a support substrate that supports the light source unit. The light source unit is provided between the sensor panel and the support substrate. Multiple protrusions of the diffusing plate are in contact with a surface of the sensor panel. The light source unit is adhered to the sensor panel via an adhesive, and the adhesive extends to the support substrate.

### BACKGROUND OF THE INVENTION

1. Field of the Invention

The present invention generally relates to a radiation detecting apparatus, and more particularly, it relates to a laminate structure of a sensor panel and a light source unit in a radiation detecting apparatus which may be useful in, for example, a medical imaging apparatus used for diagnostic purposes, or a nondestructive inspection apparatus.

2. Description of Related Art

In a commercially available radiation detecting apparatus, a sensor panel having a light detecting sensor that detects light, and a scintillator layer that converts radiation into light are arranged one above the other. Such a radiation detecting apparatus is generally referred to as an indirect-type radiation detecting apparatus. In a known sensor panel, pixels formed of planarly-arranged or stacked photoelectric conversion elements and elements such as thin film transistors (TFT) are provided as light detecting sensors.

In the indirect-type radiation detecting apparatus described above, dark current sometimes occurs in still-image capturing. Dark current is caused by, for example, irradiation history of radiation, bias application history, a residual charge remaining within a photoelectric conversion element, or a trapped charge trapped in a lattice defect within the photoelectric conversion elements. In moving-image capturing in which images are acquired multiple times, the properties of the aforementioned elements sometimes change. A change in the properties of the photoelectric conversion elements generally results in an adverse effect on the characteristics of an obtained image. In particular, if photoelectric conversion elements each having a non-monocrystalline semiconductor layer composed of, for example, amorphous silicon are used, the photoelectric conversion elements would have many defects. Thus, the effect of a trapped charge trapped in a lattice defect is significant.

As a countermeasure, there is a known technology for improving the properties of the photoelectric conversion elements by disposing a light irradiation source at the rear side of the radiation detecting apparatus and making the light irradiation source radiate light toward the photoelectric conversion elements. This technology is also referred to as, for example, light resetting, bias light irradiation, or light calibration. In this technology, with the irradiation of light, an electric charge is forcedly generated by the photoelectric conversion elements and can be read out without being used as image information, or an electric charge equivalent to an amount to be taken into a lattice defect is generated so as to compensate for a crystal lattice defect level.

For the light irradiation source mentioned above, the use of a light source unit having a structure similar to that of a light source for a liquid crystal display device has been studied. Specifically, such a light source unit has light-emitting sources along an edge thereof and spreads light planarly by using a light guide plate, a diffusing plate, and a reflective plate. Generally, the structure of a light source unit having light-emitting sources along an edge thereof is as follows. Several light-emitting sources to several hundreds of light-emitting sources are arranged in contact with the light guide plate along one edge or two opposite edges of a rectangular unit. A reflective plate is disposed below the light guide plate in close contact therewith; and a diffusing plate is disposed above the light guide plate. Generally, the light guide plate, the reflective plate, and the diffusing plate are not adhered to one another by an adhesive or the like, but are simply disposed with air layers interposed therebetween so that the optical characteristics thereof can be maintained. Furthermore, in order to supply electric power to the light-emitting sources, flexible leading wiring is disposed below the light-emitting sources and is connected to an external power supply. Because the light source unit has the above-described structure, the components included in the light source unit are generally secured by using, for example, metal or plastic fasteners or a frame.

In order to reduce the overall thickness and weight of the radiation detecting apparatus, it is desirable that the light source unit be reduced in thickness and weight. Therefore, unlike in the configuration of a light source for a liquid crystal display device, which is fixed at a position distant from the sensor panel, the light source unit in a radiation detecting apparatus needs to be disposed in close contact with the rear face of the sensor panel. In this case, there are problems in terms of a method for bonding the sensor panel and the light source unit to each other as well as the flatness of the light source unit.

For example, Japanese Patent Laid-Open Nos. 2006-322746 and 2007-163216 each propose a method for bonding a light source unit to a sensor panel while maintaining the surface flatness of the entire light source unit by disposing a support member below a region excluding the region of the diffusing plate. However, in the configuration discussed in Japanese Patent Laid-Open No. 2006-322746, the periphery of the light source unit is supported by multiple components, including the support member, an electromagnetic shield, and the light sources, so that the surface flatness may be achieved. With this configuration, it is difficult to achieve complete flatness due to, for example, dimensional errors of the components. In addition, since the light source unit is bonded along the periphery thereof alone, there is a problem in terms of the strength thereof. In order to increase the strength, the sensor panel and the light source unit need to be fully adhered to each other by using, for example, an adhesive. Such full adhesion may lead to a loss of light diffusing effect of the diffusing plate of the light source unit. On the other hand, in the configuration discussed in Japanese Patent Laid-Open No. 2007-163216, the diffusing plate has the same size as the sensor panel. Therefore, in order to bond the sensor panel and the light source unit to each other without any differences in level therebetween, the sensor panel and the light source unit need to be fully adhered to each other by using, for example, an adhesive. As mentioned above, such full adhesion may lead to a loss of light diffusing effect of the diffusing plate.

### SUMMARY OF THE INVENTION

In accordance with at least one embodiment of the present invention, the above-noted shortcomings of the related art are addressed by a radiation detecting apparatus having high surface flatness for a light source unit, a high light diffusing function, and high impact resistance while maintaining the light diffusing effect of the light source unit.

In one aspect of present invention, a radiation detecting apparatus includes a sensor panel that has a plurality of photoelectric conversion elements on one surface thereof; a light source unit that has a light guide plate, a light-emitting source disposed at a side surface of the light guide plate, a diffusing plate having a plurality of protrusions on a surface thereof and disposed at one surface of the light guide plate, and a reflective plate disposed at an opposite surface of the light guide plate from the one surface thereof; and a support substrate that supports the light source unit. The light source unit is provided between the sensor panel and the support substrate. The plurality of protrusions of the diffusing plate are in contact with an opposite surface of the sensor panel from the one surface thereof. The light source unit is adhered to the sensor panel via an adhesive member in a region excluding a region where the diffusing plate is disposed, and the adhesive member extends to the support substrate.

According to the present invention, the surface flatness of the light source unit can be maintained while the light diffusing effect is maintained. In addition, the impact resistance of the radiation detecting apparatus can be enhanced since the light source unit and the sensor panel are tightly adhered to each other by using the adhesive member.

Further features of the present invention will become apparent from the following description of exemplary embodiments with reference to the attached drawings.

### BRIEF DESCRIPTION OF THE DRAWINGS

FIG. 1 is a cross-sectional view schematically illustrating a laminate structure of a sensor panel and a light source unit in a radiation detecting apparatus according to a first embodiment.

FIG. 2 is an exploded perspective view schematically illustrating the laminate structure of the sensor panel and the light source unit in the radiation detecting apparatus according to the first embodiment.

FIGS. 3A and 3B are cross-sectional views illustrating a configuration example of the sensor panel.

FIG. 4 illustrates a configuration example of the light source unit of an edge light source type.

FIG. 5 illustrates a configuration example of the light source unit of an edge light source type.

FIGS. 6A and 6B illustrate a configuration example of the light source unit of an edge light source type.

FIG. 7 is a cross-sectional view schematically illustrating a method for manufacturing the laminate structure of the sensor panel and the light source unit according to the first embodiment.

FIG. 8 is a cross-sectional view illustrating the structure of a radiation detecting apparatus according to a second embodiment.

FIG. 9 is a cross-sectional view illustrating the laminate structure of the sensor panel and the light source unit in a radiation detecting apparatus according to a third embodiment.

FIG. 10 is a cross-sectional view schematically illustrating the laminate structure of the sensor panel and the light source unit in a radiation detecting apparatus according to a fourth embodiment.

FIG. 11 is a cross-sectional view schematically illustrating the laminate structure of the sensor panel and the light source unit in a radiation detecting apparatus according to a fifth embodiment.

FIG. 12 is a cross-sectional view schematically illustrating the laminate structure of the sensor panel and the light source unit in a radiation detecting apparatus according to a sixth embodiment.

FIG. 13 is a cross-sectional view schematically illustrating the structure of a radiation detecting apparatus according to a seventh embodiment, and shows the overall structure of the radiation detecting apparatus including a housing.

FIG. 14 schematically illustrates an application example of a radiation detecting system according to an embodiment of the present invention.

### DESCRIPTION OF THE EMBODIMENTS

Embodiments of the present invention will be described below with reference to the drawings. For the sake of convenience, with regard to each of radiation detecting apparatuses 100a to 100g according to embodiments, the side that receives radiation will be referred to as “upper side”, whereas the opposite side thereof will be referred to as “lower side”. Furthermore, a direction orthogonal to an incident direction of radiation will be referred to as “planar direction”. In each of the drawings, the direction in which radiation enters the radiation detecting apparatuses 100a to 100g is indicated by an arrow X. In each of the embodiments of the present invention, the term “radiation” refers to electromagnetic radiation including, for example, a γ ray, a β ray, in addition to X ray radiation.

### First Embodiment

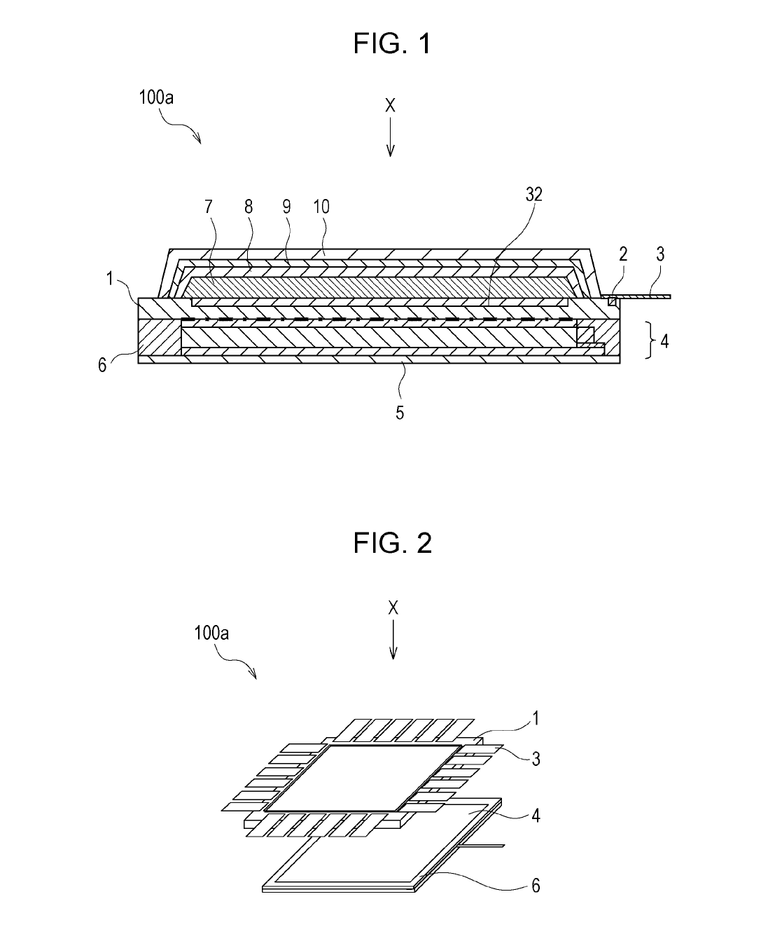

FIG. 1 is a cross-sectional view schematically illustrating a laminate structure of a sensor panel 1 and a light source unit 4 in a radiation detecting apparatus 100a according to a first embodiment of the present invention. FIG. 2 is an exploded perspective view schematically illustrating the laminate structure of the sensor panel 1 and the light source unit 4 in the radiation detecting apparatus 100a according to the first embodiment of the present invention. In FIGS. 1 and 2, reference numeral 1 denotes a sensor panel, reference numeral 2 denotes a wiring readout section, and reference numeral 3 denotes a wiring connection section. An output from the sensor panel 1 is output outside via the wiring connection section 3. Reference numeral 7 denotes a scintillator layer, reference numeral 8 denotes a reflective-layer adhesive layer, reference numeral 9 denotes a reflective layer, and reference numeral 10 denotes a reflective-layer protection layer. As shown in FIG. 1, the surface of the sensor panel 1 that receives radiation is provided with the scintillator layer 7, the reflective-layer adhesive layer 8, the reflective layer 9, and the reflective-layer protection layer 10. Reference numeral 4 denotes a light source unit, reference numeral 41 denotes light-emitting sources, reference numeral 42 denotes a flexible leading-wiring section, reference numeral 43 denotes a diffusing plate, reference numeral 44 denotes a light guide plate, and reference numeral 45 denotes a reflective plate. The light source unit 4 includes the light-emitting sources 41, the flexible leading-wiring section 42, the diffusing plate 43, the light guide plate 44, and the reflective plate 45. As shown in FIGS. 1 and 2, the light source unit 4 is fixed to the opposite surface of the sensor panel 1 from the surface thereof that receives radiation X (i.e., the surface provided with photoelectric conversion elements 13). A support substrate 5 is disposed at a side of the light source unit 4 facing away from the sensor panel 1. Accordingly, the light source unit 4 is provided between the sensor panel 1 and the support substrate 5. The sensor panel 1 and the support substrate 5 are adhered to each other by using an adhesive 6 (i.e., an adhesive member) applied along the periphery of the light source unit 4. In plan view from the incident direction of radiation X, the adhesive 6 exists only in a region outside an effective pixel region 32 of the sensor panel 1. The effective pixel region 32 is a region that can detect visible light converted from radiation. The effective pixel region 32 is provided with pixels including the photoelectric conversion elements 13. In plan view from the incident direction of radiation, a light-emitting region of the light source unit 4 is wider than the effective pixel region 32 of the sensor panel 1. Moreover, in plan view from the incident direction of radiation, the effective pixel region 32 of the sensor panel 1 is located within the light-emitting region of the light source unit 4. That is, an area of the effective pixel region 32 of the sensor panel 1 is equal to or less than an area of the light-emitting region of the light source unit 4.

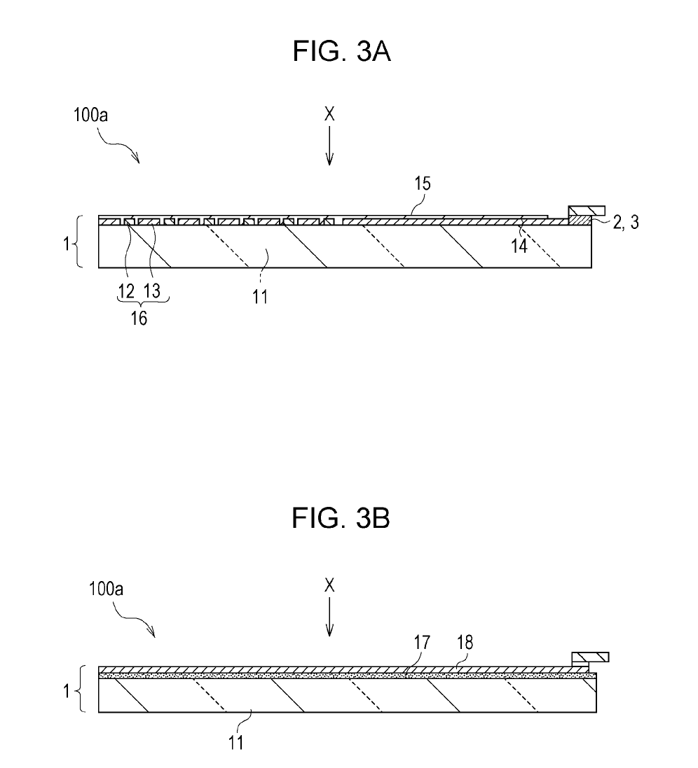

FIG. 3A is a cross-sectional view illustrating a configuration example of the sensor panel 1. In FIG. 3A, the scintillator layer 7, the reflective-layer adhesive layer 8, the reflective layer 9, and the reflective-layer protection layer 10 are not shown. A base 11, which may be formed of, for example, a glass plate or a heat-resistant resin (plastic) plate, is used. A light-receiving section 16 constituted of photoelectric conversion elements 13, wiring 12, and thin film transistors (TFT) (not shown) is formed on the base 11. The photoelectric conversion elements 13 are provided on one surface of the base 11 that receives the radiation X (i.e., the upper surface in FIG. 3A). The photoelectric conversion elements 13 of the light-receiving section 16 convert light converted from the radiation X by the scintillator layer 7 into an electric charge. The photoelectric conversion elements 13 may be composed of, for example, amorphous silicon. The configuration of the photoelectric conversion elements 13 is not particularly limited; for example, MIS sensors, PIN sensors, or TFT sensors may be used where appropriate. A signal processing circuit for processing a signal output from each photoelectric conversion element 13 and a drive circuit for driving each photoelectric conversion element 13 are provided outside the sensor panel 1. The signal processing circuit and the drive circuit are not shown in the drawings. Each photoelectric conversion element 13 is connected to the signal processing circuit and the drive circuit via the wiring 12, an electrical connection section 14, the wiring readout section 2, and the wiring connection section 3. A protection layer 15 protects the light-receiving section 16 by covering it. The protection layer 15 may be formed of an inorganic film composed of, for example SiN or SiO₂. Alternatively, referring to FIG. 3B, the sensor panel 1 may have a semiconductor substrate 18 having the light-receiving section 16 built therein and the base 11, and may be formed by bonding the semiconductor substrate 18 and the base 11 to each other by using an adhesive 17. In that case, the sensor panel 1 may be formed by bonding a plurality of semiconductor substrates 18 to the base 11.

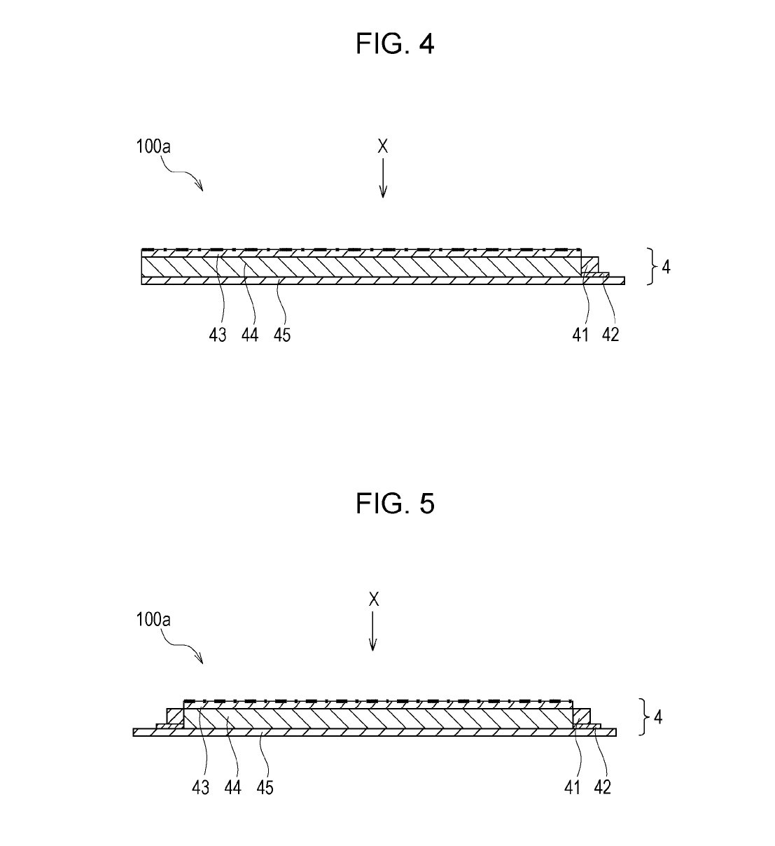

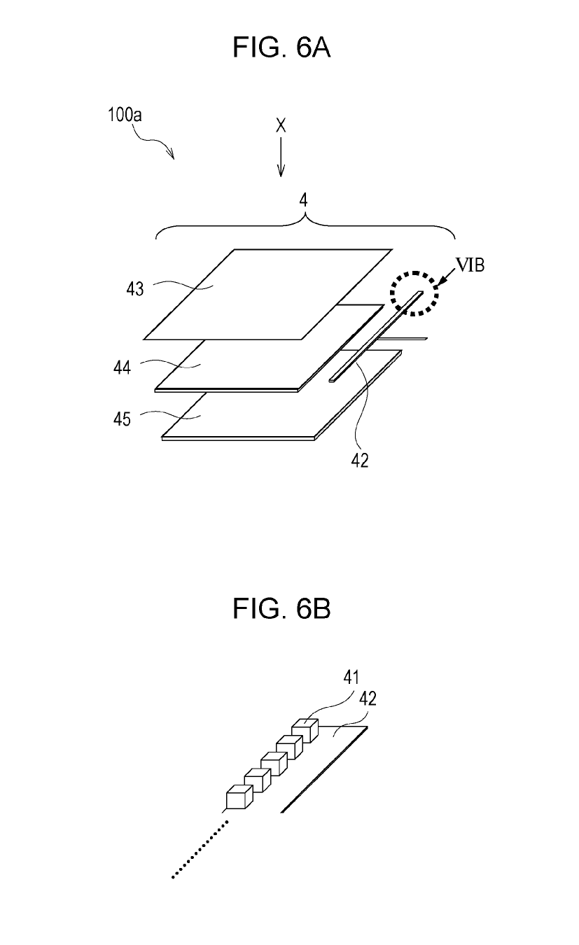

FIGS. 4 to 6B illustrate configuration examples of the light source unit 4 of an edge light source type. Specifically, FIG. 4 is a cross-sectional view illustrating an example of the light source unit 4 of a single-edge light source type. FIG. 5 is a cross-sectional view illustrating an example of the light source unit 4 of a double-edge light source type. FIG. 6A is an exploded perspective view schematically illustrating the structure of the light source unit 4 of the single-edge light source type. FIG. 6B is an enlarged view of area VIB in FIG. 6A. The light source unit 4 includes the light-emitting sources 41, the flexible leading-wiring section 42, the light guide plate 44, the diffusing plate 43, and the reflective plate 45. The light guide plate 44 has a function of radiating light emitted from the light-emitting sources 41 toward the diffusing plate 43 while causing the light to reach the edges in the planar direction. The diffusing plate 43 has a function of delivering the light exiting from the light guide plate 44 to the sensor panel 1 while diffusing the light over a wider range. The reflective plate 45 has a function of increasing the overall amount of light emitted by the light source unit 4 as well as ensuring uniform distribution of light in the planar direction by reflecting the light exiting from the light guide plate 44 in a direction away from the diffusing plate 43. Generally, a light source unit used as a light source for, for example, a liquid crystal display has a thickness of about ten to several tens of millimeters. The light guide plate especially has a large thickness. In contrast, in the first embodiment of the present invention, the light source unit 4 used is of a sheet type with an overall thickness of about several millimeters so that the radiation detecting apparatus 100a can be reduced in thickness and weight. Furthermore, a light source unit used as a light source for, for example, a liquid crystal display is fixed to an FPD (flat panel detector) via a frame composed of PET (polyethylene terephthalate) or metal. In contrast, such a frame is not used in the first embodiment of the present invention. In the first embodiment of the present invention, the adhesive 6 (e.g., an adhesive member or material) is used for fixing the light source unit 4 to the sensor panel 1.

The adhesive 6 is applied along the periphery of the light source unit 4. Specifically, in plan view from the incident direction of the radiation X, the diffusing plate 43, the light guide plate 44, and the reflective plate 45 have outside dimensions that are smaller than the outside dimensions of the sensor panel 1 and the support substrate 5. The adhesive 6 is applied so as to extend from the side surfaces of the diffusing plate 43, the light guide plate 44, and the reflective plate 45 to a surface of a peripheral region of the sensor panel 1. The adhesive 6 is also applied to a region where the light-emitting sources 41 and the flexible leading-wiring section 42 exist. This peripheral region has a freely-chosen width that ranges between several micrometers and several tens of millimeters from each side surface of the light source unit 4. In order to ensure the adhesivity from the side surfaces of the light source unit 4, it is desirable that the width be 5 mm or larger. However, the light-emitting region of the light source unit 4 (i.e., a region from which light is radiated toward the sensor panel 1) needs to be wider than the effective pixel region 32 of the sensor panel 1. Therefore, the peripheral region (i.e., an adhesive application region) needs to be narrower than the width measured from each edge of the sensor panel 1 to the effective pixel region 32.

The light-emitting sources 41 serve as light sources of the light source unit 4. For example, multiple small-size light-emitting sources 41 are arranged (as shown in FIG. 6B). Specifically, in the light source unit 4 of the single-edge light source type shown in FIG. 4, the light-emitting sources 41 are provided along a side surface extending along one edge of the light guide plate 44. In the light source unit 4 of the double-edge light source type shown in FIG. 5, the light-emitting sources 41 are provided along side surfaces extending along two opposite edges of the light guide plate 44. The light-emitting sources 41 may be appropriately selected from among, for example, fluorescent lamps, electric lamps, LEDs, CCFLs, and semiconductor lasers. The light-emitting sources 41 are positioned near the side surface or side surfaces of the light guide plate 44. In order to cause a large portion of light to enter the light guide plate 44, the light-emitting sources 41 may be configured to give directionality to the light or may have a reflecting mechanism.

The flexible leading-wiring section 42 functions as power-supply wiring for driving the light-emitting sources 41. The light-emitting sources 41 are mounted on the flexible leading-wiring section 42. The flexible leading-wiring section 42 having the light-emitting sources 41 mounted thereon serves as a light-emitting-source unit. The flexible leading-wiring section 42 extends along an edge of the light guide plate 44 along which the light-emitting sources 41 are mounted. The flexible leading-wiring section 42 is fixed to a surface of the reflective plate 45 by using, for example, adhesive tape. Furthermore, the flexible leading-wiring section 42 is provided with a connection section to be connected to the outside.

The light guide plate 44 is a plate-shaped optical member having a function of uniformly guiding the light emitted by the light-emitting sources 41 toward the diffusing plate 43 while spreading the light in the planar direction. A reflective dot pattern is formed over the surface of the light guide plate 44 facing away from the diffusing plate 43 by, for example, printing. Light entering the light guide plate 44 spreads over a wide range in the planar direction by repeatedly undergoing surface reflection. When the light becomes incident on the reflective dot pattern, the light is diffused so that light having a strong rectilinear advance property toward the diffusing plate 43 is produced. Thus, the light is radiated toward the diffusing plate 43 while being guided over a wide range in the planar direction. By changing the pitch or the diameter of the reflective dot pattern, the degree of light diffusion can be adjusted. Thus, the intensity of light emitted from a freely-chosen area can be increased. Alternatively, a configuration in which adjustment is performed to make the entire light guide plate 44 emit light uniformly is also permissible. The light guide plate 44 is an organic/inorganic resin material, such as PET. The light guide plate 44 has a thickness of, for example, about several hundreds of micrometers to several millimeters, and is generally the thickest layer in the light source unit 4.

The diffusing plate 43 has a function of radiating the light emitted by the light-emitting sources 41 and propagated through the light guide plate 44 toward the sensor panel 1 while diffusing the light in the planar direction. The surface of the diffusing plate 43 is provided with a plurality of protrusions. The protrusions of the diffusing plate 43 come into contact with the surface of the sensor panel 1 that is opposite the surface thereof provided with the photoelectric conversion elements 13. When the light travels through the plurality of protrusions and is radiated to the outside (i.e., atmosphere), the light is diffused by being refracted in various directions. Accordingly, the diffusing plate 43 diffuses the light by utilizing light refraction, which is caused by a difference between the refractive index of the material and the refractive index of an air layer that is in contact with the surface from which the light is output, and a change in the light output direction caused by the irregular shape of the surface. Therefore, if the surface of the diffusing plate 43 provided with the protrusions is embedded with, for example, an adhesive having the same refractive index as the material of the diffusing plate 43 (i.e., if the surface is not in contact with an air layer), the light diffusing effect of the diffusing plate 43 may possibly deteriorate. The diffusing plate 43 is desirably composed of, for example, PET. The diffusing plate 43 has a thickness of, for example, several micrometers to several millimeters. The protrusions on the surface desirably have a size (i.e., average roughness Ra along the center line) of, for example, 0.1 μm to 100 μm, and more desirably, 0.5 μm to 10 μm. The average roughness Ra along the center line is measured at a suitable length within a measurement length range of 0.08 mm to 25 mm.

The reflective plate 45 has a function of enhancing the light guiding performance of the light guide plate 44 as well as increasing the amount of light output toward the diffusing plate 43. The light emitted by the light-emitting sources 41 and the light output toward the opposite side of the diffusing plate 43 by the light guide plate 44 are reflected toward the light guide plate 44 by the reflective plate 45. The reflective plate 45 is desirably composed of, for example, PET or metal. The reflective plate 45 has a thickness of several micrometers to several millimeters. The surface of the reflective plate 45 that faces away from the light guide plate 44 is the outermost section of the light source unit 4. Therefore, this surface is given a scratch-proof or dent-proof treatment or is configured not to be affected by the surface texture pixels at the light guide plate 44 side of the reflective plate 45 even if the surface becomes, for example, scratched or dent.

The support substrate 5 is disposed below the reflective plate 45 of the light source unit 4 (i.e., at the side of the reflective plate 45 facing away from the light guide plate 44) and is adhered to the sensor panel 1 via the adhesive 6. The support substrate 5 is formed of a thin sheet member or a rigid plate member. In particular, the support substrate 5 is desirably a rigid plate member since it supports the light source unit 4. Furthermore, the support substrate 5 has high flatness. The support substrate 5 is desirably composed of, for example, a resin material, such as PET, or a metallic material, such as Al, Au, SUS, or Pb. The support substrate 5 may have a thickness selected from a wide thickness range. For example, the thickness may range between several micrometers and several centimeters. The support substrate 5 and the light source unit 4 are bonded to each other by using the adhesive 6. Alternatively, the two may be bonded to each other by using a material other than the adhesive 6. In addition, the reflective plate 45 and the support substrate 5 may be bonded to each other by using an adhesive. However, in that case, the reflective plate 45 is bonded to the support substrate 5 in a state where the flatness of the support substrate 5 is maintained. In plan view from the incident direction of the radiation X, the support substrate 5 has the same size as the sensor panel 1 or is larger than the sensor panel 1.

The adhesive 6 is used for adhering (joining) the sensor panel 1 and the support substrate 5 to each other. Moreover, the adhesive 6 is also in contact with the layers (i.e., the diffusing plate 43, the light guide plate 44, and the reflective plate 45) of the light source unit 4, the light-emitting sources 41, and the flexible leading-wiring section 42, and has a function of fixing these components in position. Therefore, the adhesive 6 is applied so as to extend to (or reach) both the sensor panel 1 and the support substrate 5 from the side surfaces of the light source unit 4. In plan view from the incident direction of the radiation X, the light source unit 4 has outside dimensions that are smaller than the outside dimensions of the sensor panel 1 and the outside dimensions of the support substrate 5. Therefore, when the sensor panel 1, the light source unit 4, and the support substrate 5 are stacked, a groove-like region is formed around the outer periphery thereof. The adhesive 6 is applied to this groove-like region. Consequently, the sensor panel 1, the light source unit 4, and the support substrate 5 become adhered to each other. As shown in FIGS. 1 and 2, the adhesive 6 is in contact with both the sensor panel 1 and the support substrate 5. The adhesive 6 may be embedded in the groove-like region with or without any gaps. The adhesive 6 may be composed of an organic material or an inorganic material. For example, the adhesive 6 may be an acrylic-based, epoxy-based, silicon-based, natural-rubber-based, silica-based, urethane-based, ethylene-based, polyolefin-based, polyester-based, polyurethane-based, polyamide-based, or cellulose-based adhesive. Furthermore, any one of the above adhesives may be used alone, or a mixture of the above adhesives may be used. The adhesive 6 may be composed of an antistatic moisture-proof organic or inorganic material with good cushioning properties.

The scintillator layer 7 converts radiation radiated from an external radiation source into light with a wavelength that can be detected by the photoelectric conversion elements 13. For example, a scintillator having a columnar crystal structure is known. The scintillator layer 7 having a columnar crystal structure is composed of a material containing alkali halide as a main component. Specific examples of the material of the scintillator layer 7 include CsI:Tl, CsI:Na, CsBr:Tl, NaI:Tl, LiI:Eu, and KI:Tl. If CsI is used, for example, the scintillator layer 7 can be fabricated by simultaneously depositing CsI and TlI over the sensor panel 1. Alternatively, for example, a scintillator in the form of particles or a scintillator in the form of a paste may be used as the scintillator layer 7. The scintillator layer 7 desirably has a thickness of several tens of micrometers to 1000 micrometers.

Of the light converted from radiation by and emitted from the scintillator layer 7, the reflective layer 9 reflects the light traveling away from the sensor panel 1 so as to guide the light toward the sensor panel 1. The reflective layer 9 enhances the light utilization efficiency in this manner. The reflective layer 9 may desirably be formed of a highly-reflective metal thin film composed of, for example, Al or Au, or metallic foil. Alternatively, the reflective layer 9 may be composed of, for example, a highly-reflective plastic material. The reflective layer 9 desirably has a thickness of 1 μm to 100 μm. If the reflective layer 9 is thinner than 1 μm, pin hole defects may easily occur during the formation process of the reflective layer 9. On the other hand, a reflective layer 9 thicker than 100 μm absorbs a large amount of radiation, possibly leading to a lower image quality of an acquired image or to an increased radiation dosage in a subject when capturing an image thereof.

The reflective-layer adhesive layer 8 is used for bonding the surface of the scintillator layer 7 (i.e., a scintillator protection layer (not shown) provided on the surface of the scintillator layer 7) and the reflective layer 9 to each other. The reflective-layer adhesive layer 8 may be, for example, a double-faced adhesive sheet or a liquid-curing-type adhesive. The reflective-layer adhesive layer 8 desirably has a thickness of 10 μm to 200 μm. With a reflective-layer adhesive layer 8 thinner than 10 μm, sufficient adhesive strength cannot be obtained, possibly causing the scintillator layer 7 and the reflective layer 9 to separate from each other. A reflective-layer adhesive layer 8 with a thickness larger than or equal to 200 μm may cause the light generated at the scintillator layer 7 or the light reflected by the reflective layer 9 to scatter readily at the reflective-layer adhesive layer 8. This may possibly lead to lower resolution of an image acquired by the radiation detecting apparatus 100a. The reflective-layer adhesive layer 8 may be composed of an organic material or an inorganic material. For example, the reflective-layer adhesive layer 8 may be composed of an acrylic-based, epoxy-based, silicon-based, natural-rubber-based, silica-based, urethane-based, ethylene-based, polyolefin-based, polyester-based, polyurethane-based, polyamide-based, or cellulose-based material. Any one of the above materials may be used alone, or a mixture of the above materials may be used. Alternatively, the reflective-layer adhesive layer 8 may be composed of hot-melt resin. Hot-melt resin is in its solid state at room temperature, does not contain a polarized solvent, water, or a solvent, and is defined as adhesive resin composed of a 100% nonvolatile thermoplastic material. Hot-melt resin melts as the temperature thereof increases, and solidifies as the temperature thereof decreases. Furthermore, hot-melt resin in a thermally molten state has adhesivity to other organic materials and inorganic materials, but has no adhesivity in its solid state at room temperature. Hot-melt resin is different from adhesive resin of a solvent volatile curable type, which is formed by a solvent coating method after melting thermoplastic resin in a solvent. Hot-melt resin is also different from adhesive resin of a chemical reaction type, such as epoxy resin as a representative example, which is formed by chemical reaction. The reflective-layer adhesive layer 8 may be formed independently of other components. In that case, the reflective layer 9 and the reflective-layer protection layer 10 are bonded to the scintillator layer 7 by using the reflective-layer adhesive layer 8 that is independent of the two layers. Alternatively, the reflective-layer adhesive layer 8 may be provided on the reflective layer 9 and the reflective-layer protection layer 10 in advance such that these layers are integrated into a sheet. In that case, the reflective layer 9 and the reflective-layer protection layer 10 are bonded to the scintillator layer 7 by using the reflective-layer adhesive layer 8 integrated with the reflective layer 9 and the reflective-layer protection layer 10.

The reflective-layer protection layer 10 is composed of a material that prevents the reflective layer 9 from breaking due to an impact or from corroding due to, for example, moisture. For example, the reflective-layer protection layer 10 may be composed of a film material, such as polyethylene terephthalate, polycarbonate, vinyl chloride, polyethylene naphthalate, or polyimide. The reflective-layer protection layer 10 desirably has a thickness of 10 μm to 100 μm.

The wiring readout section 2 electrically connects the electrical connection section 14 and the wiring connection section 3. The wiring readout section 2 is electrically connected to the wiring connection section 3 by, for example, an anisotropic electro-conductive adhesive. The wiring connection section 3 has, for example, an IC component mounted thereon for reading out an electric signal converted by each photoelectric conversion element 13. For example, a tape carrier package (TCP) is desirably used as the wiring connection section 3.

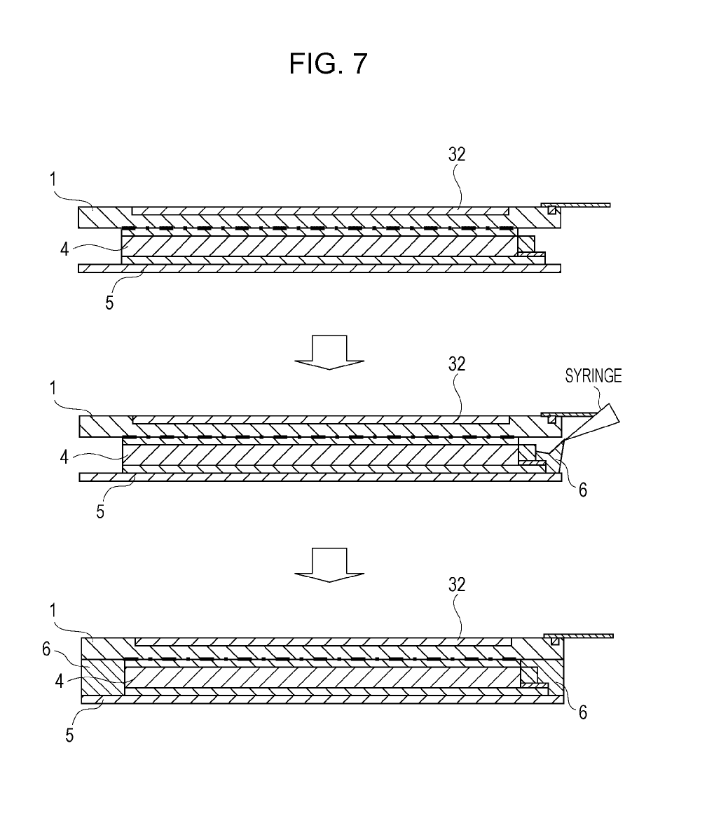

FIG. 7 is a cross-sectional view schematically illustrating a method for manufacturing the laminate structure of the sensor panel 1 and the light source unit 4 according to the first embodiment. In FIG. 7, the scintillator layer 7 and the like provided on the surface of the sensor panel 1 are not shown. As shown in an upper section of FIG. 7, the light source unit 4 whose peripheral region is open is placed on the support substrate 5, and the sensor panel 1 is placed on the light source unit 4. As shown in a mid-section of FIG. 7, the adhesive 6 is injected and applied along the periphery of the sensor panel 1 and the light source unit 4 by using, for example, a syringe. Then, as shown in a lower section of FIG. 7, the applied adhesive 6 is dried. Consequently, the laminate structure of the sensor panel 1 and the light source unit 4 according to the first embodiment is completed.

According to the first embodiment of the present invention, the light source unit 4 and the sensor panel 1 can be tightly joined to each other with the adhesive 6. Therefore, the flatness of the light source unit 4 can be maintained. In addition, the impact resistance of the radiation detecting apparatus 100a can be enhanced. Moreover, the light diffusing effect of the diffusing plate 43 can be maintained.

### Second Embodiment

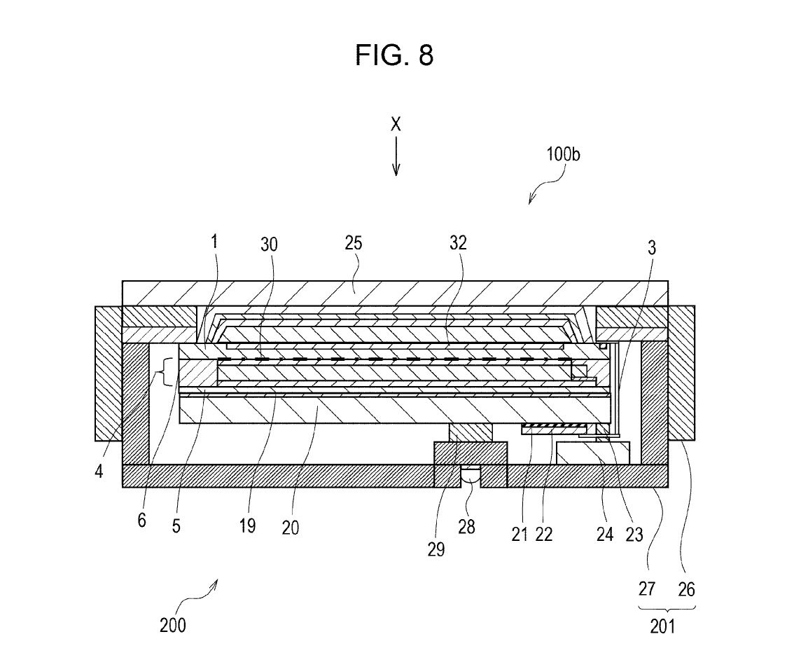

FIG. 8 is a cross-sectional view illustrating the structure of a radiation detecting apparatus 100b according to a second embodiment of the present invention. The radiation detecting apparatus 100b according to the second embodiment includes the radiation detecting apparatus 100a according to the first embodiment and a housing 200. The housing 200 includes a frame substrate 20, a front plate 25, and a cover frame 201. The cover frame 201 has an upper cover frame 26 and a lower cover frame 27. As shown in FIG. 8, the front plate 25 is disposed above the scintillator layer 7 and the sensor panel 1 bonded to the light source unit 4. The sensor panel 1 bonded to the light source unit 4 is surrounded by the front plate 25, the upper cover frame 26, and the lower cover frame 27. Accordingly, the housing 200 serves as an outer sheath for the radiation detecting apparatus 100b. A sponge 31 is provided between the upper cover frame 26 and the lower cover frame 27. The support substrate 5 is disposed below the light source unit 4 and is bonded to the frame substrate 20 via a substrate adhesive 19. The support substrate 5 bonded to the frame substrate 20 is fixed to the lower cover frame 27 via a sensor fixation member 29 by using a screw 28. An electric substrate 22 is disposed below the frame substrate 20 via an insulation sheet 21. The electric substrate 22 is connected to the wiring connection section 3. The wiring connection section 3 is protected by a cushion sheet 23 and is in contact with the lower cover frame 27 via a spacer member 24. Although FIG. 8 illustrates a configuration in which there is one fixation area at the right side where the electric substrate 22 and the frame substrate 20 are fixed to the lower cover frame 27 via the sensor fixation member 29 and the screw 28, there are multiple fixation areas, such as at the left side and in the middle of the apparatus.

The frame substrate 20 supports the sensor panel 1 and the light source unit 4. The frame substrate 20 is bonded to the support substrate 5 by using the substrate adhesive 19. The frame substrate 20 desirably has a thickness of several millimeters to several tens of millimeters. Since the frame substrate 20 needs enough strength to support the sensor panel 1 and the light source unit 4, the thickness thereof is desirably 10 mm or larger. The frame substrate 20 may be composed of metal, such as Al or SUS, or a resin material, such as PET. The frame substrate 20 is fixed to the lower cover frame 27 via the sensor fixation member 29 by using the screw 28. The frame substrate 20 may alternatively be configured to function as the support substrate 5. In that case, the substrate adhesive 19 is not necessary.

The front plate 25 is disposed at the outermost side of the radiation detecting apparatus 100b that receives the radiation X. Therefore, the front plate 25 is composed of a selected material that is harmless to humans and that has high radiation transmittance. Furthermore, the front plate 25 is desirably composed of a material that is highly resistant to, for example, impact and moisture. Specifically, the front plate 25 may be composed of carbon or CFRP. The front plate 25 has a thickness of several millimeters to several tens of millimeters.

The cover frame 201 includes the upper cover frame 26 and the lower cover frame 27. The upper cover frame 26 and the lower cover frame 27 constitute the housing 200 of the radiation detecting apparatus 100b together with the front plate 25. The housing 200 functions as a reinforcement member that ensures the strength of the radiation detecting apparatus 100b. The upper cover frame 26 and the lower cover frame 27 are composed of a lightweight material that is resistant to, for example, impact and vibration. For example, the cover frame 201 may be composed of a common resin material (plastic), an organic/inorganic resin material, or metal.

### Third Embodiment

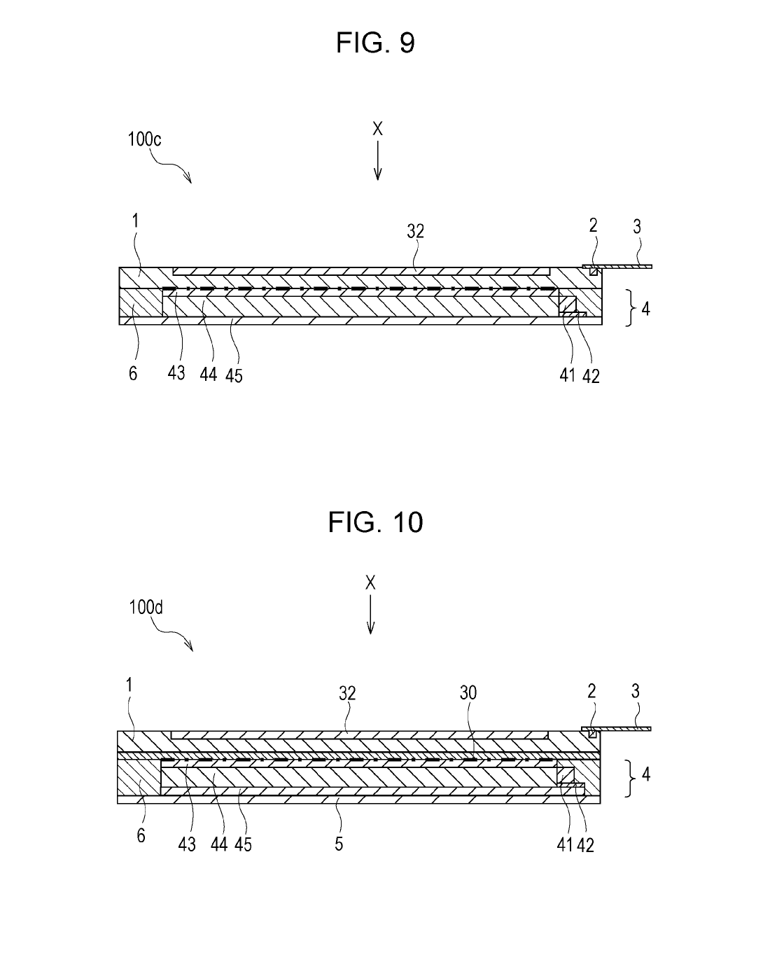

FIG. 9 is a cross-sectional view illustrating the laminate structure of the sensor panel 1 and the light source unit 4 in a radiation detecting apparatus 100c according to a third embodiment of the present invention. In FIG. 9, the scintillator layer 7 and the like provided on the surface of the sensor panel 1 are not shown (the same applies for FIGS. 10 to 12). In the third embodiment, the reflective plate 45 in the light source unit 4 also has a function of the support substrate 5 serving as a reinforcement member for ensuring the strength. In this configuration, the reflective plate 45 is a flat plate member having a reflective function for reflecting light, as well as having enough strength for supporting the sensor panel 1 and the light source unit 4. The reflective plate 45 may be composed of, for example, a resin material, such as PET, or a metallic material, such as Al, Au, SUS, or Pb. The reflective plate 45 may have a thickness selected from a wide thickness range. For example, the thickness may range between several micrometers and several centimeters.

### Fourth Embodiment

FIG. 10 is a cross-sectional view schematically illustrating the laminate structure of the sensor panel 1 and the light source unit 4 in a radiation detecting apparatus 100d according to a fourth embodiment of the present invention. In the fourth embodiment, a sheet 30 is provided between the sensor panel 1 and the light source unit 4. The sheet 30 has high flatness and comes into contact with the surface of the diffusing plate 43 without bending. Furthermore, the sheet 30 has high transmittance such that light output from the diffusing plate 43 toward the sensor panel 1 is sufficiently transmitted through the sheet 30 so as to reach the sensor panel 1. The sensor panel 1 and the sheet 30 may be entirely bonded to each other by using, for example, an adhesive sheet, or the two may be not bonded to each other. If the two are to be bonded to each other, an optical adhesive sheet is used. The sheet 30 and the light source unit 4 are joined to each other by applying the adhesive 6 therebetween such that the adhesive 6 extends to the periphery of the sheet 30 from the side surfaces of the light source unit 4. The adhesive 6 is also applied so as to extend to the support substrate 5. Therefore, the surface of the sheet 30 facing the light source unit 4 and the support substrate 5 are joined to each other by the adhesive 6. The adhesive 6 is applied along the side surfaces of the light source unit 4 at the outer side of a region where the diffusing plate 43 is disposed. The sheet 30 is desirably composed of a material with high light transmittance and high flatness. Examples of such a material include a plate or a sheet composed of a polymer resin material, such as PET, or a glass plate. The sheet 30 has a thickness of several micrometers to 5 cm. If the sheet 30 has a thickness larger than or equal to 5 cm, the light output from the light source unit 4 would be excessively diffused over a wide range as it is transmitted through the sheet 30. This may possibly decrease the intensity of light reaching the sensor panel 1. In plan view from the incident direction of the radiation X, the outside dimensions of the sheet 30 are the same as or smaller than those of the sensor panel 1, but are larger than or equal to those of the diffusing plate 43 of the light source unit 4. A sheet 30 that is larger than the sensor panel 1 would lead to inconvenience in the assembly process. On the other hand, a sheet 30 that is smaller than the diffusing plate 43 of the light source unit 4 may possibly lead to reduced intensity of light reaching the sensor panel 1, as well as reduced uniformity in light distribution. By using the sheet 30, the sensor panel 1 can be disposed on a flat surface without losing the optical characteristics (i.e., light diffusing performance) of the diffusing plate 43 of the light source unit 4.

### Fifth Embodiment

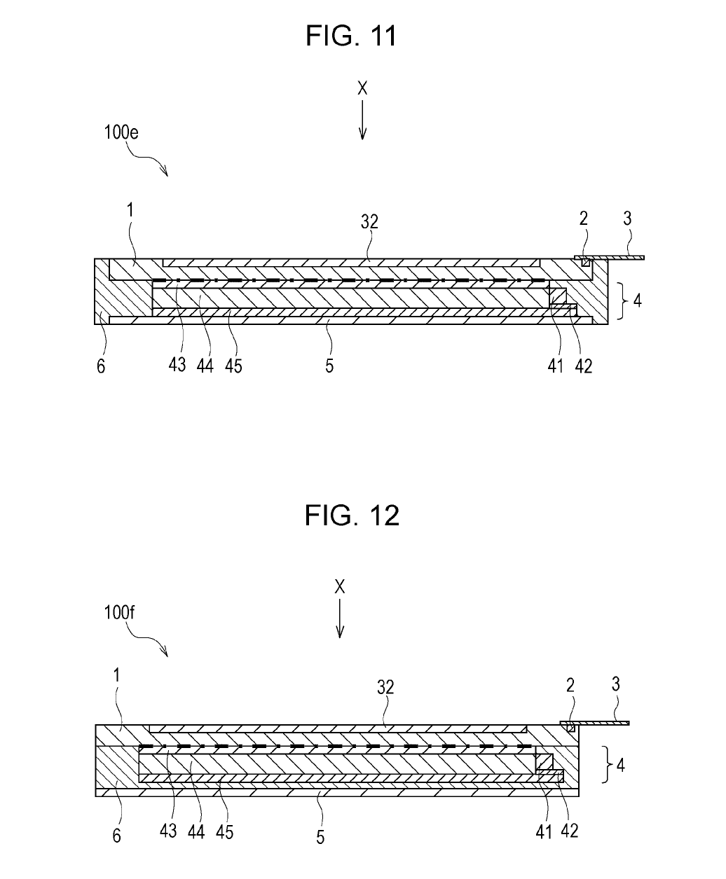

FIG. 11 is a cross-sectional view schematically illustrating the laminate structure of the sensor panel 1 and the light source unit 4 in a radiation detecting apparatus 100e according to a fifth embodiment of the present invention. As shown in FIG. 11, in the fifth embodiment, the adhesive 6 used for adhering the sensor panel 1 and the support substrate 5 to each other is applied so as to extend to the side surfaces of the sensor panel 1 and the side surfaces of the support substrate 5. With this configuration, the edges of the sensor panel 1 and the support substrate 5 can be protected from, for example, an impact, thereby preventing damages, such as cracking and chipping.

### Sixth Embodiment

FIG. 12 is a cross-sectional view schematically illustrating the laminate structure of the sensor panel 1 and the light source unit 4 in a radiation detecting apparatus 100f according to a sixth embodiment. As shown in FIG. 12, the adhesive 6 used for adhering the sensor panel 1 and the support substrate 5 to each other also serves as the adhesive 6 for adhering the reflective plate 45 and the support substrate 5 to each other. Specifically, the adhesive 6 is applied to the outer peripheral area of the radiation detecting apparatus 100f, and the adhesive 6 is also applied so as to extend between the light source unit 4 (i.e., the reflective plate 45 of the light source unit 4) and the support substrate 5. With this configuration, the sensor panel 1 and the support substrate 5 are tightly adhered to each other, and an additional adhesive for adhering the reflective plate 45 and the support substrate 5 to each other is not necessary.

### Seventh Embodiment

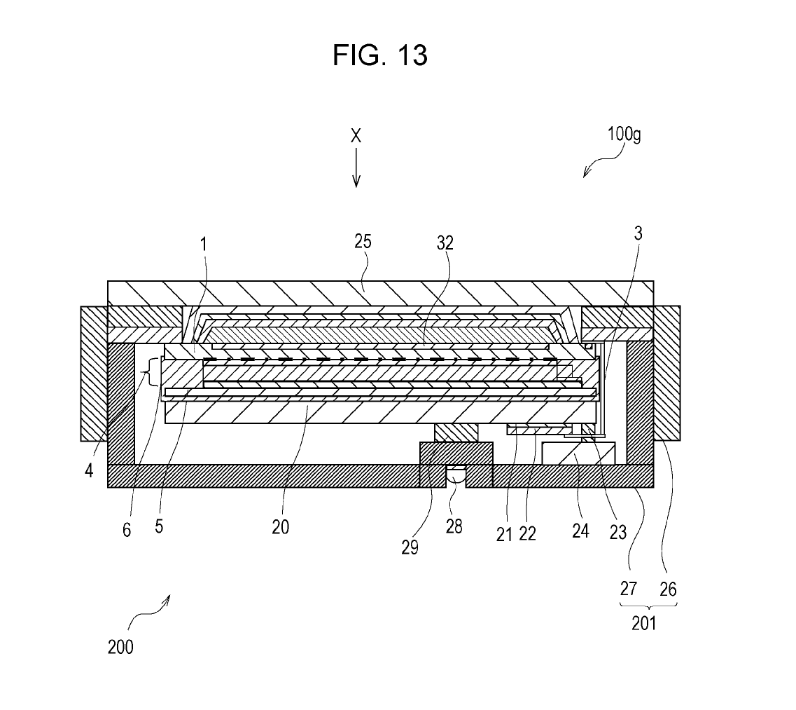

FIG. 13 is a cross-sectional view schematically illustrating the structure of a radiation detecting apparatus 100g according to a seventh embodiment, and shows the overall structure of the radiation detecting apparatus 100g including the housing 200. As shown in FIG. 13, the adhesive 6 used for adhering the sensor panel 1 and the support substrate 5 to each other also serves as an adhesive for adhering the support substrate 5 and the frame substrate 20 to each other. Specifically, the adhesive 6 is applied to the outer peripheral area of the light source unit 4 and the like, and the adhesive 6 is also applied between the support substrate 5 and the frame substrate 20. With this configuration, the sensor panel 1 and the support substrate 5 are tightly adhered to each other, and an additional adhesive for adhering the support substrate 5 and the frame substrate 20 to each other is not necessary.

### Eighth Embodiment

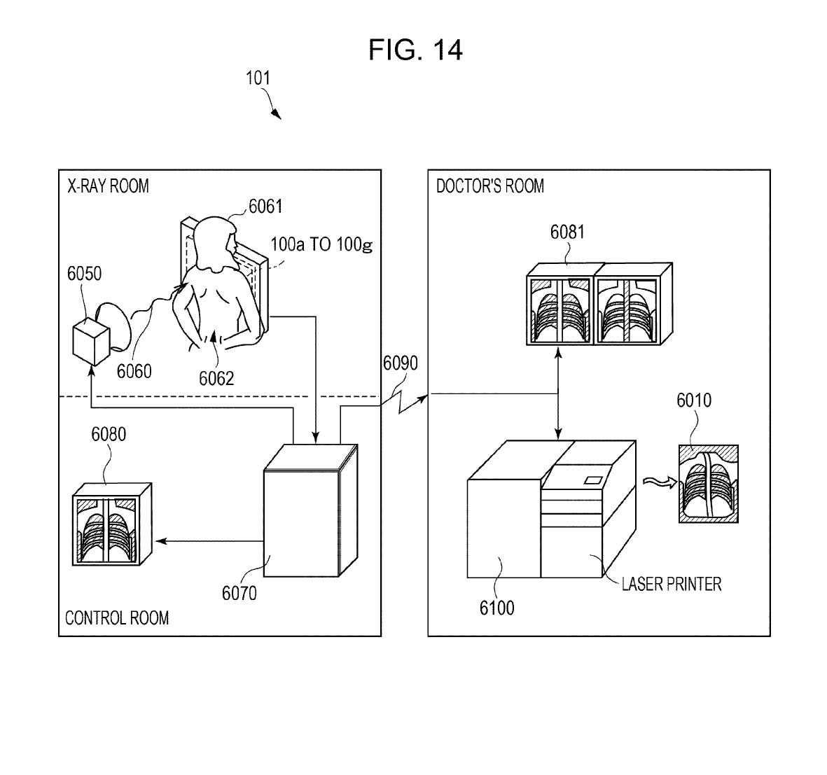

FIG. 14 schematically illustrates an application example of a radiation detecting system 101 according to an embodiment of the present invention. In the radiation detecting system 101 according to the embodiment of the present invention, any one of the radiation detecting apparatuses 100a to 100g according to the above embodiments of the present invention is employed. The radiation detecting system 101 includes an X-ray tube 6050 serving as a radiation source, one of the radiation detecting apparatuses 100a to 100g (referred to as “radiation detecting apparatus 100” hereinafter), an image processor 6070 serving as a signal processor, and display screens 6080 and 6081 serving as display units. In addition to the above components, the radiation detecting system 101 includes a film processor 6100 and a printer. Radiation (e.g., X rays) generated by the X-ray tube 6050 serving as a radiation source penetrates through a body part 6062 of a subject 6061 and enters the radiation detecting apparatus 100 (image sensor). The radiation entering the radiation detecting apparatus 100 includes internal information about the chest 6062 of the subject 6061. When the radiation enters the radiation detecting apparatus 100, the scintillator layer 7 (see FIG. 1) emits light in accordance with the incident radiation, and the photoelectric conversion elements 13 photoelectrically convert the light emitted by the scintillator layer 7. Thus, electrical information about the body part 6062 of the subject 6061 is obtained. This information is digitally converted and is output to the image processor 6070 serving as a signal processor. The image processor 6070 serving as a signal processor is a computer that includes a central processing unit (CPU), a random access memory (RAM), and a read-only memory (ROM). Furthermore, the image processor 6070 has a storage medium serving as a storage unit capable of storing various kinds of information. For example, the image processor 6070 has a built-in hard disk drive (HDD), a built-in solid state drive (SSD), or a built-in recordable optical disk drive as a storage unit. Alternatively, the image processor 6070 may be externally connectable to an HDD, an SSD, or a recordable optical disk drive serving as a storage unit. The image processor 6070 serving as a signal processor performs predetermined signal processing on this information and makes the display 6080 display this information. Thus, the subject or an examiner can observe the information in the form of an image. Furthermore, the image processor 6070 is capable of storing this information into the HDD, the SSD, or the recordable optical disk drive serving as a storage unit. Moreover, the image processor 6070 may have an interface serving as an information transmitting unit 6090 that can transmit the information to the outside. The interface serving as a transmitting unit 6090 may be, for example, an interface connectable to a local area network (LAN) or a telephone line. The image processor 6070 can transmit this information to a remote location via the interface serving as a transmitting unit. For example, the image processor 6070 transmits this information to a doctor's room located distant from a radiation-image capturing room where the radiation detecting apparatus 100 is installed. Thus, a doctor, for example, can examine the subject from a remote location. Furthermore, the radiation detecting system 101 can also record this information onto a film 6210 by using the film processor 6100 serving as a recording unit.

According to each of the above embodiments of the present invention, the surface flatness of the light source unit 4 can be maintained while the light diffusing effect of the diffusing plate 43 is maintained. Furthermore, since the light source unit 4 and the sensor panel 1 are tightly adhered to each other by the adhesive 6, the impact resistance of each of the radiation detecting apparatuses 100a to 100g can be enhanced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. Furthermore, the embodiments described above are merely examples of the invention and may be combined, where appropriate.

This application claims the benefit of Japanese Patent Application No. 2012-219633 filed Oct. 1, 2012, which is hereby incorporated by reference herein in its entirety.

What is claimed is:

1. A radiation detecting apparatus comprising:
a sensor panel that has a plurality of photoelectric conversion elements on one surface thereof;
a light source unit that has a light guide plate, a light-emitting source disposed at a side surface of the light guide plate, a diffusing plate having a plurality of protrusions on a surface thereof and disposed at one surface of the light guide plate, and a reflective plate disposed at an opposite surface of the light guide plate from the one surface thereof; and
a support substrate that supports the light source unit,
wherein the light source unit is provided between the sensor panel and the support substrate,
wherein the plurality of protrusions of the diffusing plate are in contact with an opposite surface of the sensor panel from the one surface thereof, and
wherein the light source unit is adhered to the sensor panel via an adhesive member in a region excluding a region where the diffusing plate is disposed, and the adhesive member extends to the support substrate.

2. The radiation detecting apparatus according to claim 1,
wherein the support substrate is adhered to a frame serving as a reinforcement member for the radiation detecting apparatus, or the support substrate serves as a reinforcement member for the radiation detecting apparatus.

3. The radiation detecting apparatus according to claim 1,
wherein the reflective plate functions as a frame serving as a reinforcement member for the radiation detecting apparatus.

4. The radiation detecting apparatus according to claim 1, further comprising:
a sheet provided between the opposite surface of the sensor panel and the light source unit,
wherein a surface of the sheet facing the light source unit and the support substrate are adhered to each other by the adhesive member in the region excluding the region where the diffusing plate is disposed.

5. The radiation detecting apparatus according to claim 1,
wherein the adhesive member extends to at least one of the sensor panel and the support substrate.

6. The radiation detecting apparatus according to claim 1,
wherein the adhesive member extends between the reflective plate of the light source unit and the support substrate.

7. The radiation detecting apparatus according to claim 2,
wherein the adhesive member is applied between the support substrate and the frame.

8. A radiation detecting system comprising:
the radiation detecting apparatus according to claim 1;
a signal processor configured to process a signal from the radiation detecting apparatus;
a storage unit configured to store the signal from the signal processor;
a display unit configured to display the signal from the signal processor; and
a transmitting unit configured to transmit the signal from the signal processor.
